(19) United States
(12) Patent Application Publication
(10) Pub. No.: US 2025/0081320 A1
(43) Pub. Date: Mar. 6, 2025

(54) EXTREME ULTRAVIOLET LIGHT GENERATING DEVICE

(71) Applicant: Samsung Electronics Co., Ltd., Suwon-si (KR)

(72) Inventors: Injae LEE, Suwon-si (KR); Ohkug KWON, Suwon-si (KR); Youngduk SUH, Suwon-si (KR); Sunghyup KIM, Suwon-si (KR); Jeonggil KIM, Suwon-si (KR); Yebin NAM, Suwon-si (KR); Daegeun YOON, Suwon-si (KR); Seungpyo HONG, Suwon-si (KR)

(73) Assignee: Samsung Electronics Co., Ltd., Suwon-si (KR)

(21) Appl. No.: 18/638,916

(22) Filed: Apr. 18, 2024

(30) Foreign Application Priority Data
Sep. 4, 2023 (KR) 10-2023-0117232

(51) Int. Cl. H05G 2/00; G03F 7/00

(52) U.S. Cl. CPC H05G 2/006; G03F 7/70033; H05G 2/008

(57) ABSTRACT

An extreme ultraviolet (EUV) light generating device includes a vessel having an internal space, a droplet generator generating droplets to be supplied to the internal space, a droplet emitter emitting the droplets generated by the droplet generator to the internal space, a laser light source generating a laser beam to generate EUV light by reaction with the droplets, a condensing mirror adjacent to the laser light source to at least partially surround the laser light source and concentrating EUV light on an intermediate focus (IF), and gas lock nozzles around the IF to respectively constitute rows and ejecting a flow control gas to the internal space, wherein a tilted direction of a gas lock nozzle in at least one of the rows is tilted in a direction consistent with a tilted direction of a sidewall of the vessel with respect to a central axis direction of the internal space.

### CROSS-REFERENCE TO RELATED APPLICATION

This application is based on and claims priority under 35 U.S.C. § 119 to Korean Patent Application No. 10-2023-0117232, filed on Sep. 4, 2023, in the Korean Intellectual Property Office, the disclosure of which is incorporated by reference herein in its entirety.

### BACKGROUND

The inventive concepts relate to extreme ultraviolet light generating devices.

As fine process techniques for semiconductors have been continuously required and existing techniques have reached the limit, lithography processes using extreme ultraviolet (EUV) light have been spotlighted as alternative solutions. Minimum process dimensions of semiconductor circuits formed by lithography processes depend on wavelengths of light sources. Therefore, to more finely process semiconductor devices, wavelengths of light sources used in lithography processes need to be shorter. Because EUV light has a short wavelength of about 13.5 nm, finer semiconductor circuits may be made by using EUV light. As methods of generating EUV light, laser-produced plasma (LPP) methods, in which laser beams are irradiated onto metal droplets, such as tin, are widely used.

### SUMMARY

The inventive concepts provide extreme ultraviolet light generating devices having improved reliability.

According to some aspects of the inventive concepts, there is provided an extreme ultraviolet (EUV) light generating device including a vessel having an internal space, a droplet generator configured to generate droplets that are to be supplied to the internal space of the vessel, a droplet emitter configured to emit the droplets, generated by the droplet generator, to the internal space of the vessel, a laser light source configured to generate a laser beam to generate EUV light by reaction with the droplets in the internal space of the vessel, a condensing mirror arranged adjacent to the laser light source to surround at least a portion of the laser light source, the condensing mirror being configured to concentrate EUV light on an intermediate focus (IF), and a plurality of gas lock nozzles arranged around the IF to respectively constitute a plurality of rows, each of the plurality of gas lock nozzles being configured to eject a flow control gas to the internal space of the vessel, wherein a gas lock nozzle in at least one of the plurality of rows is tilted in a direction that is consistent with a direction in which a sidewall of the vessel is tilted with respect to a central axis direction of the internal space of the vessel.

According to some aspects of the inventive concepts, there is provided an extreme ultraviolet (EUV) light generating device including a vessel having an internal space, a droplet generator configured to generate droplets that are to be supplied to the internal space of the vessel, a droplet emitter configured to emit the droplets, generated by the droplet generator, to the internal space of the vessel, a laser light source configured to generate a laser beam to generate EUV light by reaction with the droplets in the internal space of the vessel, a condensing mirror arranged adjacent to the laser light source to surround at least a portion of the laser light source, the condensing mirror being configured to concentrate EUV light on an intermediate focus (IF), and a plurality of gas lock nozzles arranged around the IF to respectively constitute a plurality of rows, each of the plurality of gas lock nozzles being configured to eject a flow control gas to the internal space of the vessel, wherein a gas lock nozzle in at least one of the plurality of rows is tilted in a direction that is consistent with a direction in which a sidewall of the vessel is tilted with respect to a central axis direction of the internal space of the vessel, and a difference between an angle, at which the gas lock nozzle in the at least one row is tilted with respect to the central axis direction of the internal space of the vessel, and an angle, at which the sidewall of the vessel is tilted with respect to the central axis direction of the internal space of the vessel, is 5 degrees) (° or less.

According to some aspects of the inventive concepts, there is provided An extreme ultraviolet (EUV) light generating device configured to output EUV light generating device that constitutes a lithography apparatus comprising, first optics configured to cause EUV light, which is output from the EUV light generating device, to be incident on a mask that reflects EUV light, second optics configured to cause EUV light, which is reflected by the mask, to be incident on a substrate, a mask stage, on which the mask is arranged, a substrate stage, on which the substrate is arranged, a vessel having an internal space, an exhaust line on one side of the vessel, an exhaust unit configured to discharge a gas from the internal space of the vessel through the exhaust line, a droplet generator configured to generate droplets that are to be supplied to the internal space of the vessel, a droplet emitter configured to emit the droplets, generated by the droplet generator, to the internal space of the vessel, a droplet flow path configured to guide the droplets generated by the droplet generator to the droplet emitter, a droplet collector configured to collect the droplets emitted from the droplet emitter, a laser light source configured to generate a laser beam to generate EUV light by reaction with the droplets in the internal space of the vessel, a condensing mirror arranged adjacent to the laser light source to surround at least a portion of the laser light source, the condensing mirror being configured to concentrate EUV light on an intermediate focus (IF), a plurality of gas lock nozzles arranged around the IF to respectively constitute a plurality of rows, each of the plurality of gas lock nozzles being configured to eject a flow control gas to the internal space of the vessel, a gas lock nozzle in at least one of the plurality of rows is tilted in a direction that is consistent with a direction in which a sidewall of the vessel is tilted with respect to a central axis direction of the internal space of the vessel, a difference between an angle, at which the gas lock nozzle in the at least one row is tilted with respect to the central axis direction of the internal space of the vessel, an angle, at which the sidewall of the vessel is tilted with respect to the central axis direction of the internal space of the vessel, is 5 degrees (°) or less.

### BRIEF DESCRIPTION OF THE DRAWINGS

Embodiments will be more clearly understood from the following detailed description taken in conjunction with the accompanying drawings in which:

FIG. 1 is a configuration diagram schematically illustrating an extreme ultraviolet light generating device, according to some example embodiments;

FIG. 2 is a diagram illustrating an appearance of an extreme ultraviolet light generating device in an intermediate focus region, according to some example embodiments;

FIG. 3A is an enlarged view of an intermediate focus region of FIG. 1, according to some example embodiments;

FIG. 3B is an enlarged view of the intermediate focus region of FIG. 1, according to some example embodiments;

FIG. 4 is an enlarged view of a region I of FIG. 3A, according to some example embodiments;

FIG. 5 is an enlarged view of the region I of FIG. 3A, according to some example embodiments;

FIG. 6 is a diagram illustrating results of gas-flow simulation for an internal space of a vessel along with the change of a gas lock nozzle;

FIG. 7 is a diagram schematically illustrating a configuration of a lithography apparatus, according to some example embodiments; and

FIG. 8 is a diagram illustrating a control unit of FIG. 7 in detail, according to some example embodiments.

### DETAILED DESCRIPTION

Example embodiments of the inventive concepts may have various changes thereto and be implemented in various ways, and thus, some example embodiments are illustrated in the accompanying drawings and will be described in detail. However, it should be understood that it is not intended to limit the inventive concepts to the specific disclosed embodiments. In addition, it will be understood that the following example embodiments are provided for illustration only and various changes and modifications can be applied thereto without departing from the scope of the inventive concepts.

It should be understood that all examples or terms used herein are only for describing the inventive concepts in detail, and that the scope of the inventive concepts are not limited by these examples or terms unless defined by claims.

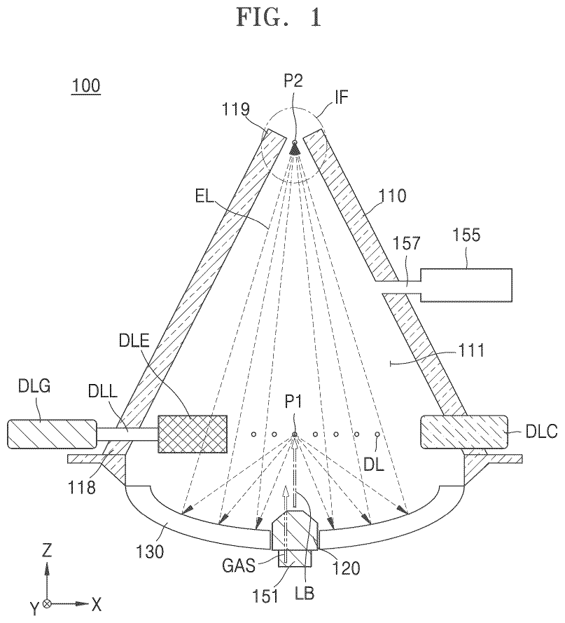

FIG. 1 is a configuration diagram schematically illustrating an extreme ultraviolet light generating device, according to some example embodiments.

Referring to FIG. 1, an extreme ultraviolet (EUV) light generating device 100 may generate EUV light EL for a lithography process. For example, EUV light EL generated by the EUV light generating device 100 may have a wavelength of about or exactly 4 nm to about or exactly 124 nm. In some example embodiments, EUV light EL may have a wavelength of about or exactly 4 nm to about or exactly 20 nm. In some example embodiments, EUV light EL may have a wavelength of about or exactly 13.5 nm. The EUV light generating device 100 may include a plasma-based light source or a synchrotron radiation light source. Here, the plasma-based light source refers to a light source in the manner of generating plasma and using light emitted due to plasma and may include a laser-produced plasma (LPP) light source, a discharge-produced plasma (DPP) light source, or the like. In some example embodiments, the EUV light generating device 100 may include an LPP light source.

The EUV light generating device 100 may include a first end 118 and a second end 119, which are opposite to each other, and include a vessel 110 extending from the first end 118 to the second end 119 to form an internal space 111.

In addition, the EUV light generating device 100 may include a droplet generator DLG configured to generate droplets DL, which are to be supplied to the internal space 111 of the vessel 110, a droplet ejector DLE configured to eject the droplets DL to the internal space 111, a droplet flow path DLL guiding the droplets DL generated by the droplet generator DLG to the droplet ejector DLE, and a droplet collector DLC configured to collect the droplets DL ejected from the droplet ejector DLE.

In addition, the EUV light generating device 100 may include a laser light source 120, which is configured to generate a laser beam LB to emit EUV light EL by reacting with the droplets DL in the internal space 111, and a condensing mirror 130, which is arranged adjacent to the laser light source 120 and the first end 118 of the vessel 110 to surround at least a portion of the laser light source 120 and concentrates EUV light EL on an intermediate focus IF.

In addition, the EUV light generating device 100 may include an exhaust line 157 on one side of the vessel 110, an exhaust unit 155 configured to discharge a gas from the internal space 111 of the vessel 110 through the exhaust line 157, and a main gas source 151 located under the laser light source 120 in a vertical direction (Z direction) and configured to supply a gas GAS forming an updraft in the internal space 111 of the vessel 110. Hereinafter, the respective components are described in detail.

The vessel 110 may provide the internal space 111 in which EUV light EL is generated. For example, the internal space 111 of the vessel 110 may be maintained in a vacuum. Because the internal space 111 of the vessel 110 is maintained in a vacuum, EUV light EL may be prevented from being absorbed by air. For example, the pressure of the internal space 111 of the vessel 110 may be about or exactly 1.0 Torr to about or exactly 1.8 Torr.

The vessel 110 may include the first end 118 and the second end 119, which are opposite to each other. The internal space 111 of the vessel 110 may extend from the first end 118 to the second end 119. The first end 118 of the vessel 110 may be a portion, through which the laser beam LB used in generating EUV light EL is introduced, or a portion adjacent to the condensing mirror 130. The second end 119 of the vessel 110 may be a portion through which EUV light EL generated in the vessel 110 is emitted.

In some example embodiments, the internal space 111 of the vessel 110 may have a tapered shape having a decreasing width away from the first end 118 toward the second end 119 of the vessel 110. For example, the internal space 111 of the vessel 110 may have, but is not limited to, a cone shape narrowing away from the first end 118 toward the second end 119 of the vessel 110.

The droplet ejector DLE may supply the droplets DL to the internal space 111 of the vessel 110. The droplet ejector DLE may cause a cycle of supplying the droplets DL by ejection to be constant or according to a desired or selected pattern. Here, the droplets DL are a source material for generating EUV light EL, and EUV light EL may be generated by an interaction between the droplets DL and the laser beam BL introduced to the internal space 111 of the vessel 110. For example, the droplets DL may include at least one of tin (Sn), lithium (Li), or xenon (Xe). For example, the droplets DL may include at least one of tin (Sn), a tin compound (for example, SnBr₄, SnBr₂, or SnH), or a tin alloy (for example, Sn—Ga, Sn—In, or Sn—In—Ga).

The droplet ejector DLE may supply the droplets DL in a path that intersects with a travel path of the laser beam BL introduced to the internal space 111 of the vessel 110. For example, when the laser beam BL introduced to the internal space 111 of the vessel 110 travels in the vertical direction (for example, the Z direction), the droplet ejector DLE may eject the droplets DL in a horizontal direction (for example, the X direction and/or the Y direction) that is perpendicular to the vertical direction (for example, the Z direction). For example, the droplet ejector DLE may eject the droplets DL toward a first position P1, which is preset (or, alternatively, desired or determined), in the internal space 111 of the vessel 110. The first position P1 in the vessel 110 is a position at which a movement path of the droplets DL intersects with the travel path of the laser beam LB, and EUV light EL may be generated by reaction between the laser beam LB and the droplets DL, which have reached the first position P1.

The droplet collector DLC may be arranged at an end of the movement path of the droplets DL, which are ejected from the droplet ejector DLE, and collect the droplets DL ejected from the droplet ejector DLE. Droplets DL not reacting with the laser beam LB, from among the droplets DL ejected from the droplet ejector DLE, may be collected by the droplet collector DLC.

The laser light source 120 may output the laser beam LB to the internal space 111 of the vessel 110. The laser beam LB provided by the laser light source 120 may be introduced into the vessel 110 and may travel toward the first position P1 in the vessel 110. In some example embodiments, the laser light source 120 may be configured to output gas laser light generated by using a gas as a gain medium. For example, the laser light source 120 may be configured to output carbon dioxide (CO₂) laser light, helium-neon (He—Ne) laser light, nitrogen laser light, excimer laser light, or the like.

The condensing mirror 130 may be arranged adjacent to the first end 118 of the vessel 110. The condensing mirror 130 may be configured to reflect EUV light EL formed by reaction between the laser beam LB and the droplets DL and concentrate EUV light EL on a second position P2 that is adjacent to the second end 119 of the vessel 110. For example, the condensing mirror 130 may have an ellipsoidal geometrical structure having two focuses. For example, the condensing mirror 130 may have the first position P1, at which the laser beam LB meets the droplets DL, as a first focus and have the second position P2, at which EUV light EL reflected by the condensing mirror 130 is concentrated, as a second focus. The second focus may be referred to as the intermediate focus IF.

The main gas source 151 may be configured to supply the gas GAS to the internal space 111 of the vessel 110. The main gas source 151 may supply the gas GAS having extremely low reactivity to the internal space 111 of the vessel 110. For example, the gas GAS supplied from the main gas source 151 may include hydrogen (H₂), helium (He), argon (Ar), hydrogen bromide (HBr), or a combination thereof. Although FIG. 1 illustrates an example in which the gas GAS supplied by the main gas source 151 is supplied from under the laser light source 120 in the condensing mirror 130 to the internal space 111 of the vessel 110, the gas GAS supplied by the main gas source 151 may be introduced to the internal space 111 adjacent to the first end 118 of the vessel 110 through a plurality of inflow ports arranged in the vessel 110.

The exhaust unit 155 may be configured to remove a gas from the internal space 111 of the vessel 110. The exhaust unit 155 may discharge a gas in the internal space 111 of the vessel 110 through the exhaust line 157 of the vessel 110. The exhaust line 157 of the vessel 110 may be arranged between the first end 118 and the second end 119 of the vessel 110. One or more exhaust lines 157 may be arranged in the vessel 110. When a plurality of exhaust lines 157 are arranged in the vessel 110, the plurality of exhaust lines 157 may be at substantially the same height, but the inventive concepts are not limited thereto.

The exhaust unit 155 may include an exhaust pump connected to the vessel 110 via the exhaust line 157. In addition, the exhaust unit 155 may further include a regulator for adjusting the amount of gas discharged through the exhaust line 157, a scrubber for scrubbing gas discharged through the exhaust line 157, or the like.

The gas GAS supplied to the internal space 111 of the vessel 110 by the main gas source 151 may form an updraft, which is gas flow from the first end 118 toward the second end 119 of the vessel 110. That is, the gas GAS supplied by the main gas source 151 may rise from the first end 118 toward the second end 119 of the vessel 110 and may be discharged out of the vessel 110 through the exhaust line 157 of the vessel 110. Such flow of the gas GAS may remove contaminants remaining on an inner wall of the vessel 110 and a surface of the condensing mirror 130 and remove heat from the vessel 110 and components, such as the condensing mirror 130 and the like.

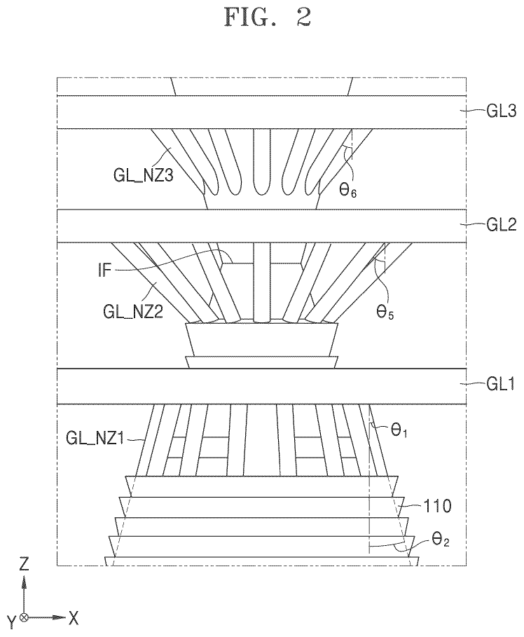

FIG. 2 is a diagram illustrating an appearance of an EUV light generating device in an intermediate focus region, according to some example embodiments. Descriptions are made by referring to FIG. 1 in addition to FIG. 2.

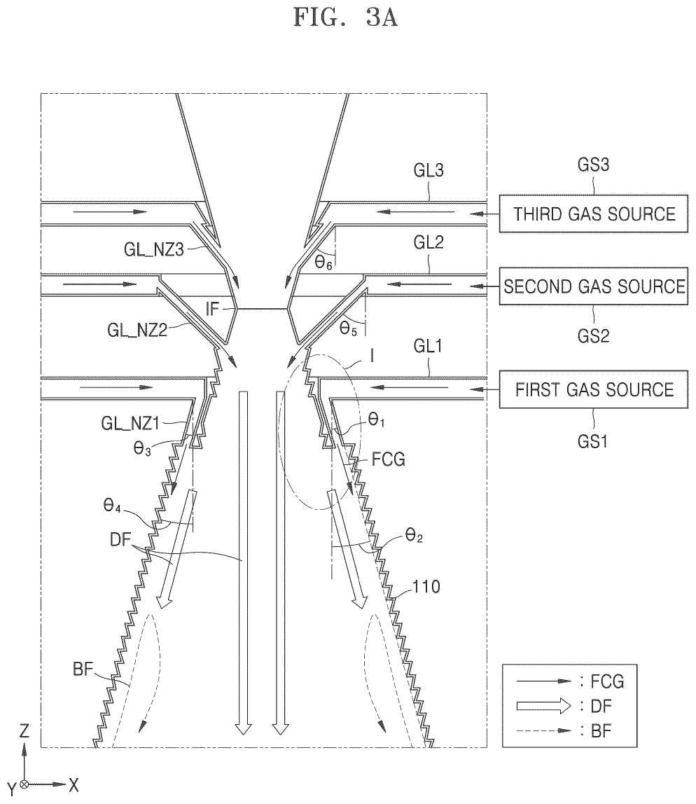

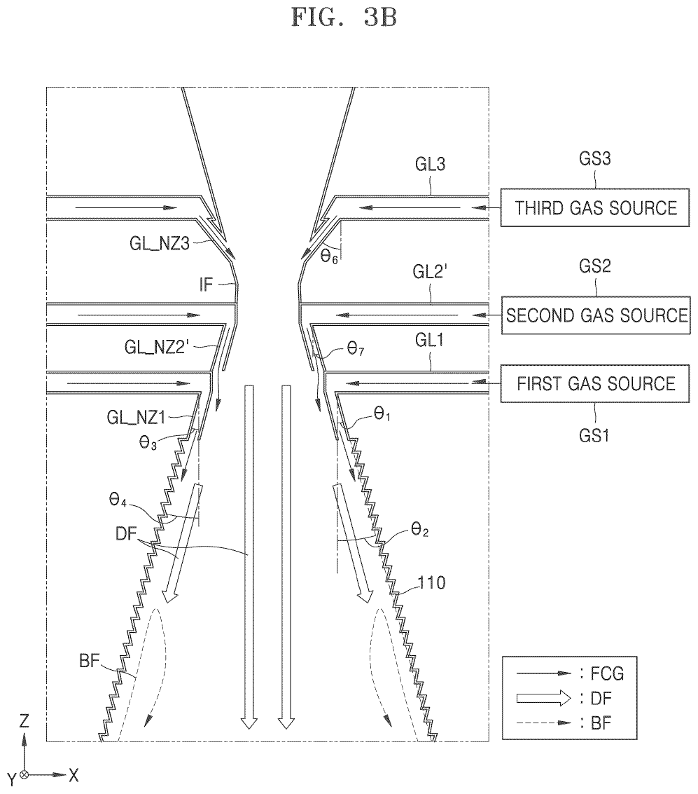

Referring to FIGS. 1 and 2, although a first gas lock GL1, a second gas lock GL2, and a third gas lock GL3 may be stacked in three layers above the vessel 110 in the vertical direction Z, the number of stacked layers of gas locks is not limited thereto and may be more or less than three. The gas locks (that is, GL1, GL2, and GL3) may be respectively connected with gas lock nozzles respectively constituting a plurality of rows, and the gas lock nozzles respectively constituting the plurality of rows may be connected with the vessel 110 to eject a dynamic gas as a flow control gas to the internal space 111. According to some example embodiments, a first gas lock nozzle GL_NZ1 connected to the first gas lock GL1 may be connected to the vessel 110 to eject a dynamic gas as a flow control gas. A second gas lock nozzle GL_NZ2 connected to the second gas lock GL2, which is arranged vertically above the first gas lock GL1, may be connected to the vessel 110 to eject a dynamic gas as a flow control gas. A third gas lock nozzle GL_NZ3 connected to the third gas lock GL3, which is arranged vertically above the second gas lock GL2, may be connected to the vessel 110 to eject a dynamic gas as a flow control gas. Although a plurality of gas locks (that is, GL1, GL2, and GL3) shown in FIG. 2 may each be commonly referred to as a dynamic gas lock (DGL) and a plurality of gas lock nozzles (that is, GL_NZ1, GL_NZ2, and GL_NZ3) may each be commonly referred to as a dynamic gas lock nozzle, the plurality of gas locks (that is, GL1, GL2, and GL3) and the plurality of gas lock nozzles (that is, GL_NZ1, GL_NZ2, and GL_NZ3) are respectively referred to as gas locks and gas lock nozzles for convenience of description. In addition, each of the gas lock nozzles (that is, GL_NZ1, GL_NZ2, and GL_NZ3) may be provided in a plural number. In FIGS. 3A and 3B, although each of the gas lock nozzles (that is, GL_NZ1, GL_NZ2, and GL_NZ3) is shown as being provided as two gas lock nozzles respectively arranged one-by-one on left and right sides in the horizontal direction, this is only for convenience of illustration and the inventive concepts are not limited thereto.

Referring to FIGS. 1 and 2, the vessel 110 may have a horizontal cross-sectional area increasing downwards in the vertical direction (Z direction). For example, the sidewall of the vessel 110 may be tilted at θ₂ with respect to a central axis direction of the internal space 111 of the vessel 110. In at least one of the plurality of rows respectively including the gas lock nozzles (that is, GL_NZ1, GL_NZ2, and GL_NZ3), a horizontal cross-sectional area obtained by connecting the respective centers of a plurality of gas lock nozzles in the at least one row to each other may increase downwards in the vertical direction (Z direction), similar to the vessel 110. On the contrary, in at least one of the plurality of rows respectively including the gas lock nozzles (that is, GL_NZ1, GL_NZ2, and GL_NZ3), a horizontal cross-sectional area obtained by connecting the respective centers of a plurality of gas lock nozzles in the at least one row to each other may decrease downwards in the vertical direction (Z direction), as opposed to the vessel 110.

According to some example embodiments shown in the figures of the inventive concepts, a horizontal cross-sectional area obtained by connecting the respective centers of a plurality of gas lock nozzles, which are included in the first gas lock nozzle GL_NZ1, to each other may decrease downwards in the vertical direction (Z direction), as opposed to the vessel 110. The first gas lock nozzle GL_NZ1 may be tilted at 01 with respect to the central axis direction of the internal space 111 of the vessel 110. A horizontal cross-sectional area obtained by connecting the respective centers of a plurality of gas lock nozzles, which are included in the second gas lock nozzle GL_NZ2, to each other may decrease downwards in the vertical direction (Z direction), as opposed to the vessel 110. The second gas lock nozzle GL_NZ2 may be tilted at 05 with respect to the central axis direction of the internal space 111 of the vessel 110. A horizontal cross-sectional area obtained by connecting the respective centers of a plurality of gas lock nozzles, which are included in the third gas lock nozzle GL_NZ3, to each other may decrease downwards in the vertical direction (Z direction), as opposed to the vessel 110. The third gas lock nozzle GL_NZ3 may be tilted at 06 with respect to the central axis direction of the internal space 111 of the vessel 110. The number, shapes, and tilted angles of gas lock nozzles in each of the plurality of rows are not limited to the examples shown in the figures of the inventive concepts. The plurality of gas locks (that is, GL1, GL2, and GL3) and the plurality of gas lock nozzles (that is, GL_NZ1, GL_NZ2, and GL_NZ3) may each include a metal material. For example, the plurality of gas locks (that is, GL1, GL2, and GL3) and the plurality of gas lock nozzles (that is, GL_NZ1, GL_NZ2, and GL_NZ3) may each include aluminum (Al), tungsten (W), or a combination thereof. Alternatively, in some example embodiments, the plurality of gas locks (that is, GL1, GL2, and GL3) and the plurality of gas lock nozzles (that is, GL_NZ1, GL_NZ2, and GL_NZ3) may each include ceramic or a polymer. For example, the plurality of gas locks (that is, GL1, GL2, and GL3) and the plurality of gas lock nozzles (that is, GL_NZ1, GL_NZ2, and GL_NZ3) may each include glass, quartz, or Teflon.

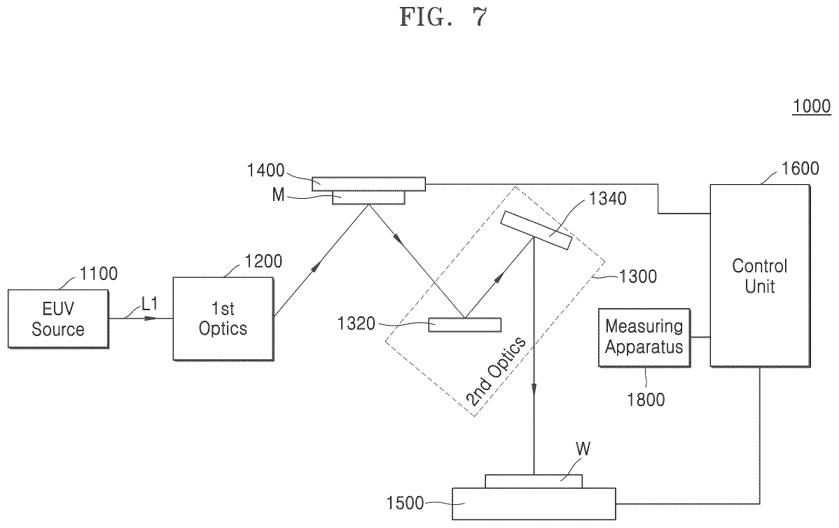

The intermediate focus IF may have a diameter of 6 mm or less and have a circular cross-sectional shape. EUV light may pass through the intermediate focus IF, and a plurality of gas lock nozzles supplying a flow control gas to the intermediate focus IF may suppress tin particles involved in an EUV generation reaction from permeating a mask (see M of FIG. 7) region.

FIG. 3A is an enlarged view of the intermediate focus region of FIG. 1, according to some example embodiments. FIG. 3B is an enlarged view of the intermediate focus region of FIG. 1, according to some example embodiments. Descriptions are made by referring to FIG. 1 in addition to FIGS. 3A and 3B.

Referring to FIG. 3A, a gas source for supplying a flow control gas FCG to a gas lock may be connected to one side of each of the plurality of gas locks (that is, GL1, GL2, and GL3). For example, a first gas source GS1 may be connected to one side of the first gas lock GL1, and the flow control gas FCG generated by the first gas source GS1 may be ejected from the first gas lock nozzle GL_NZ1 through the first gas lock GL1 and thus supplied to the internal space 111 of the vessel 110. The flow control gas FCG is a gas for controlling gas flow in the internal space 111 of the vessel 110 and may include a gas having extremely low reactivity. For example, the flow control gas FCG may include an inert gas. For example, the flow control gas FCG may include hydrogen (H₂), helium (He), argon (Ar), hydrogen bromide (HBr), or a combination thereof. The flow control gas FCG supplied from a plurality of gas sources (that is, GS1, GS2, and GS3) may have a material and/or a material composition, which is the same as or different from that of the gas GAS provided by the main gas source 151.

The gas-flow type of the flow control gas FCG may vary depending on a tilted angle of a nozzle of a gas lock. For example, the direction (that is, θ₁ or θ₃) in which the first gas lock nozzle GL_NZ1 is tilted with respect to the central axis of the internal space 111 may be the same as the direction (that is, θ₂ or θ₄) in which the sidewall of the vessel 110 is tilted with respect to the central axis of the internal space 111. When the direction in which the first gas lock nozzle GL_NZ1 constituting a plurality of rows is tilted with respect to the central axis of the internal space 111 is consistent with the direction in which the sidewall of the vessel 110 is tilted with respect to the central axis of the internal space 111, the gas flow of the flow control gas FCG ejected from the first gas lock nozzle GL_NZ1 may be formed along the wall surface of the vessel 110. The direction in which each of the second gas lock nozzle GL_NZ2 and the third gas lock nozzle GL_NZ3 is tilted with respect to the central axis of the internal space 111 of the vessel 110 may not be the same as the direction in which the sidewall of the vessel 110 is tilted with respect to the central axis of the internal space 111 of the vessel 110. When the direction (that is, θ₅ or θ₆) in which each of the second gas lock nozzle GL_NZ2 and the third gas lock nozzle GL_NZ3, respectively constituting a plurality of rows, is tilted with respect to the central axis of the internal space 111 of the vessel 110 is opposite to the direction (that is, θ₂) in which the sidewall of the vessel 110 is tilted with respect to the central axis of the internal space 111 of the vessel 110 (that is, not aligned with, for example, offset by about or exactly 90 degrees), the gas flow of the flow control gas FCG ejected from each of the second gas lock nozzle GL_NZ2 and the third gas lock nozzle GL_NZ3 may be formed along the center of the internal space 111 of the vessel 110.

The flow control gas FCG ejected from each gas lock nozzle may supply down flow DF, which is a downdraft, to the internal space 111 of the vessel 110. The down flow DF may be formed downwards in the vertical direction (Z direction) along the central axis of the internal space 111 of the vessel 110 or formed along the wall surface of the vessel 110. The down flow DF may physically suppress the residue of tin droplets involved in an EUV light generation process in the EUV light generating device 100 from passing through the intermediate focus IF and traveling toward a mask (see M of FIG. 7).

Referring to FIGS. 1 to 3B, the down flow DF may meet the updraft formed by the gas GAS, which is generated by the main gas source 151, and thus form back flow BF, which is gas flow rising along the inner wall of the vessel 110. A region in which the back flow BF is generated may be consistent with a tin accumulation region described below. In general, a spitting phenomenon occurs such that the residue of the droplets DL accumulating in an inner wall region adjacent to the second end 119 of the vessel 110, for example, in the aforementioned region in which the back flow BF is generated, reacts with a gas in the internal space 111 of the vessel 110 to generate particles having sizes of about or exactly 1 μm. There is concern that the particles generated due to the spitting phenomenon are emitted outside the vessel 110 through the second end 119 of the vessel 110. When the particles generated due to the spitting phenomenon are emitted outside the vessel 110 through the second end 119 of the vessel 110, the particles may be attached to other components of a lithography apparatus, which are arranged in a downstream region of the EUV light generating device 100, and thus cause facility defects. In particular, when the particles generated due to the spitting phenomenon are attached to a mask, the reliability of a lithography process may be significantly deteriorated due to mask defects. According to some example embodiments, because the first gas lock nozzle GL_NZ1 is tilted in a direction that is consistent with the direction in which the sidewall of the vessel 110 is tilted with respect to the central axis direction of the internal space 111 of the vessel 110, the first gas lock nozzle GL_NZ1 may eject the flow control gas FCG downwards along the wall surface of the vessel 110, thereby suppressing the back flow BF, which is gas flow rising along the inner wall of the vessel 110. Therefore, because the residue of the droplets DL is suppressed from moving to the vicinity of the second end 119 of the vessel 110 along with the back flow BF, which is gas flow rising along the inner wall of the vessel 110, the residue of the droplets DL may be suppressed from accumulating in the vicinity of the second end 119 of the vessel 110. Because the residue of the droplets DL is suppressed from accumulating in the vicinity of the second end 119 of the vessel 110, mask defect issues due to the particles generated by the spitting phenomenon may be reduced, and eventually, the reliability of a lithography process using a lithography apparatus may improve.

Referring to FIG. 3B, the direction (that is, θ₇) in which a second gas lock nozzle GL_NZ2′ is tilted with respect to the central axis of the internal space 111 of the vessel 110 may be the same as the direction (that is, θ₂) in which the sidewall of the vessel 110 is tilted with respect to the central axis of the internal space 111 of the vessel 110. When the direction in which the second gas lock nozzle GL_NZ2′ constituting a plurality of rows is tilted with respect to the central axis direction of the internal space 111 of the vessel 110 is consistent with the direction in which the sidewall of the vessel 110 is tilted with respect to the central axis direction of the internal space 111 of the vessel 110, the gas flow of the flow control gas FCG ejected from the second gas lock nozzle GL_NZ2′ may be formed along the wall surface of the vessel 110. Although the direction in which the third gas lock nozzle GL_NZ3 is tilted with respect to the central axis of the internal space 111 of the vessel 110 may not be the same as the direction in which the sidewall of the vessel 110 is tilted with respect to the central axis of the internal space 111 of the vessel 110, the inventive concepts are not limited thereto. In other words, a gas lock nozzle in at least one of the plurality of rows of gas lock nozzles may be tilted in a direction that is opposite to the direction in which the sidewall of the vessel 110 is tilted with respect to the central axis direction of the internal space 111 of the vessel 110. However, as described above, when the direction (that is, θ₆) in which the third gas lock nozzle GL_NZ3 constituting a plurality of rows is tilted with respect to the central axis direction of the internal space 111 of the vessel 110 is opposite to the direction (that is, θ₂) in which the sidewall of the vessel 110 is tilted with respect to the central axis direction of the internal space 111 of the vessel 110, the gas flow of the flow control gas FCG ejected from the third gas lock nozzle GL_NZ3 may be formed along the center of the internal space 111 of the vessel 110. When the direction in which the third gas lock nozzle GL_NZ3 is tilted with respect to the central axis of the internal space 111 of the vessel 110 is the same as the direction in which each of the first gas lock nozzle GL_NZ1 and the second gas lock nozzle GL_NZ2′ is tilted with respect to the central axis of the internal space 111 of the vessel 110, the gas flow of the flow control gas FCG may be formed along the wall surface of the vessel 110 rather than formed along the center of the internal space 111 of the vessel 110. Because each of the first gas lock nozzle GL_NZ1 and the second gas lock nozzle GL_NZ2′ is tilted in a direction that is consistent with the direction in which the sidewall of the vessel 110 is tilted with respect to the central axis direction of the internal space 111 of the vessel 110, each of the first gas lock nozzle GL_NZ1 and the second gas lock nozzle GL_NZ2′ may eject the flow control gas FCG downwards along the wall surface of vessel 110, thereby suppressing or effectively suppressing the back flow BF, which is gas flow rising along the inner wall of the vessel 110. Therefore, because the residue of the droplets DL is effectively suppressed from moving (for example, such that no residue or an undetectable amount moves) to the vicinity of the second end 119 of the vessel 110 along with the back flow BF, which is gas flow rising along the inner wall of the vessel 110, the residue of the droplets DL may be effectively suppressed from accumulating in the vicinity of the second end 119 of the vessel 110. Because the residue of the droplets DL is effectively suppressed from accumulating in the vicinity of the second end 119 of the vessel 110, mask defect issues due to the particles generated by the spitting phenomenon may be reduced, and eventually, the reliability of a lithography process using a lithography apparatus may effectively improve.

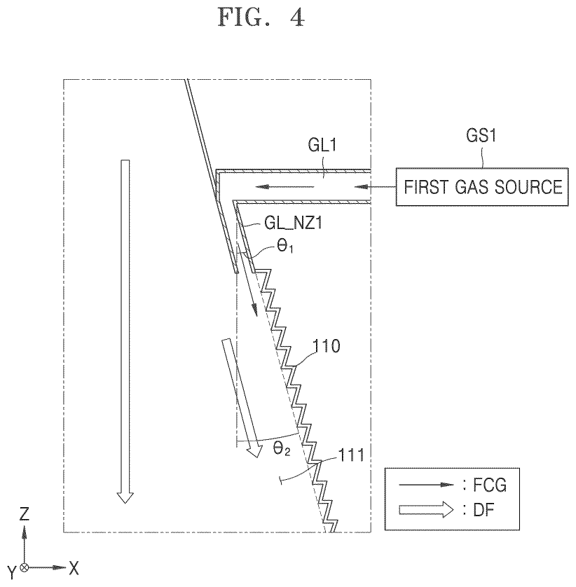

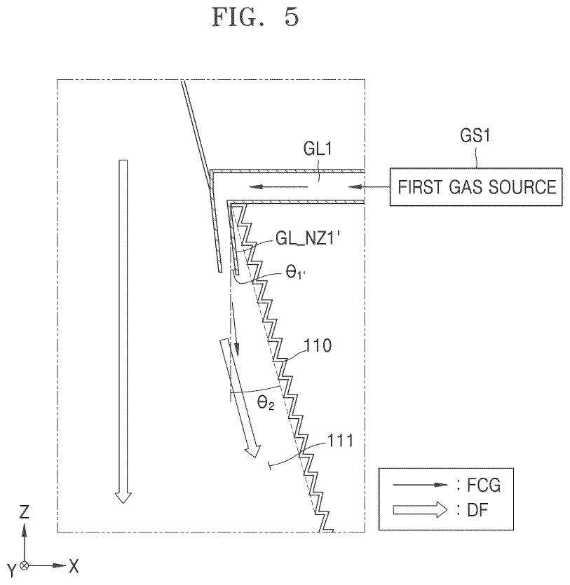

FIG. 4 is an enlarged view of a region I of FIG. 3A, according to some example embodiments. FIG. 5 is an enlarged view of the region I of FIG. 3A, according to some example embodiments.

Referring to FIGS. 4 and 5, the flow control gas FCG generated by the first gas source GS1 may sequentially pass through the first gas lock GL1 and the first gas lock nozzle GL_NZ1 in the stated order to be ejected to the internal space 111 that is formed by the vessel 110. Although the first gas lock nozzle GL_NZ1, which is connected with the first gas lock GL1, is shown in FIGS. 4 and 5 as including one first gas lock nozzle GL_NZ1 for convenience of illustration, the first gas lock nozzle GL_NZ1 may include a plurality first gas lock nozzles GL_NZ1 and the number of first gas lock nozzles GL_NZ1 is not limited thereto.

The first gas lock nozzle GL_NZ1 may be in contact with the upper surface of the vessel 110, as shown in FIG. 4. In addition, as shown in FIG. 5, the side surface of the first gas lock nozzle GL_NZ1′ may not be in contact with the inner wall of the vessel 110 and may be arranged apart from the inner wall of the vessel 110 by as much as a certain distance to extend toward the internal space 111 of the vessel 110, but the inventive concepts are not limited thereto.

Similar to the first gas lock nozzle GL_NZ1 or GL_NZ′, when the direction in which a gas lock nozzle is tilted with respect to the central axis direction of the internal space 111 of the vessel 110 is consistent with the direction in which the sidewall of the vessel 110 is tilted with respect to the central axis direction of the internal space 111 of the vessel 110, the angle θ₁ at which the first gas lock nozzle GL_NZ1 is tilted with respect to the central axis direction of the internal space 111 of the vessel 110 may be equal to the angle θ₂ at which the sidewall of the vessel 110 is tilted with respect to the central axis direction of the internal space 111 of the vessel 110 (that is, θ₁=θ₂), as shown in FIG. 4. In addition, as shown in FIG. 5, the difference between the angle θ₁′, at which the first gas lock nozzle GL_NZ′ is tilted with respect to the central axis direction of the internal space 111 of the vessel 110, and the angle θ₂, at which the sidewall of the vessel 110 is tilted with respect to the central axis direction of the internal space 111 of the vessel 110, may be about or exactly 5 degrees (°) or less (for example, a positive 5 degree (°) difference to a negative 5 degree (°) difference), but the inventive concepts are not limited thereto. In other words, when the direction in which each of the gas lock nozzles (that is, GL_NZ1, GL_NZ2, and GL_NZ3) respectively constituting a plurality of rows is tilted with respect to the central axis direction of the internal space 111 of the vessel 110 is consistent with the direction in which the sidewall of the vessel 110 is tilted with respect to the central axis direction of the internal space 111 of the vessel 110, the difference between the angle, at which each of the gas lock nozzles (that is, GL_NZ1, GL_NZ2, and GL_NZ3) is tilted with respect to the central axis direction of the internal space 111 of the vessel 110, and the angle, at which the sidewall of the vessel 110 is tilted with respect to the central axis direction of the internal space 111 of the vessel 110, may be about or exactly 5 degrees (°) or less. As in FIGS. 4 and 5, the tilted direction of the first gas lock nozzle GL_NZ1 in the vicinity of the intermediate focus IF may be the same as the tilted direction of the sidewall of the vessel 110, thereby forming the first gas lock nozzle GL_NZ1 in a diverging type. By doing this, a dynamic gas, that is, the flow control gas FCG, may effectively form a downdraft in the vicinity of the inner wall of the vessel 110, thereby lowering a generation point of the back flow BF on the wall surface of the vessel 110 adjacent to the intermediate focus IF. The generation point of the back flow BF is lowered down, and thus, tin may be suppressed from accumulating.

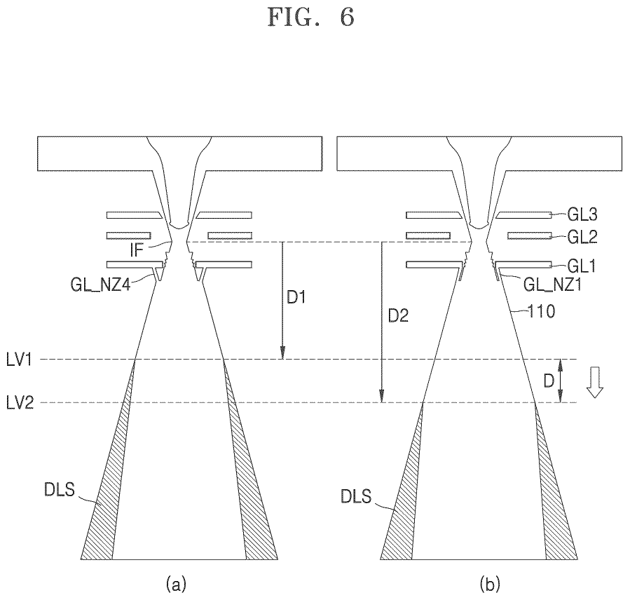

FIG. 6 is a diagram illustrating results of gas-flow simulation for an internal space of a vessel along with the change of a gas lock nozzle.

In FIG. 6, (a) illustrates a fourth gas lock nozzle GL_NZ4 when the direction in which the fourth gas lock nozzle GL_NZ4 connected to the first gas lock GL1 is tilted with respect to the central axis of the internal space 111 of the vessel 110 is opposite to the direction in which the sidewall of the vessel 110 is tilted with respect to the central axis of the internal space 111 of the vessel 110. In FIG. 6, (b) illustrates the first gas lock nozzle GL_NZ1 when the direction in which the first gas lock nozzle GL_NZ1 connected to the first gas lock GL1 is tilted with respect to the central axis of the internal space 111 of the vessel 110 is the same as the direction in which the sidewall of the vessel 110 is tilted with respect to the central axis of the internal space 111 of the vessel 110, such as in the example embodiments of FIGS. 1-5. As the generation of EUV light progresses, tin may accumulate, and the shape and height of a tin accumulation region DLS as simulation results are shown in each of (a) and (b). The height of the tin accumulation region DLS, in which tin accumulates, in the vertical direction (Z direction) is shown as a level, and it can be seen that tin accumulates up to a first level LV1 on the inner wall of the vessel 110 in the case of (a) and tin accumulates up to a second level LV2 on the inner wall of the vessel 110 in the case of (b). It can be seen that the first level LV1 is higher than the second level LV2. The distance in the vertical direction (Z direction) from the intermediate focus IF to the first level LV1 may be defined to be a first distance D1, the distance in the vertical direction (Z direction) from the intermediate focus IF to the second level LV2 may be defined to be a second distance D2, and the gap between the first distance D1 and the second distance D2 may be defined to be a distance difference D. Referring to FIG. 6, it can be seen that an EUV light generating device including the first gas lock nozzle GL_NZ1 has a tin accumulation region DLS at a lower level in the vertical direction (Z direction) than an EUV light generating device including the fourth gas lock nozzle GL_NZ4 and that the second distance D2 is greater than the first distance D1.

Therefore, it can be seen that the shape of the first gas lock nozzle GL_NZ1 causes the generation point of the back flow BF, shown in FIG. 5, to be lower than the shape of the fourth gas lock nozzle GL_NZ4, thereby suppressing tin from accumulating, in a vessel 110 of similar configuration. For example, the first distance D1 was measured to be about or exactly 22.6 mm in the case of (a) and the second distance D2 was measured to be about or exactly 34.9 mm in the case of (b).

According to some example embodiments, from among gas lock nozzles respectively constituting a plurality of rows, the first gas lock nozzle GL_NZ1 may provide a uniform downdraft throughout all regions in the circumferential direction to have a high level of consistency for flow control. Therefore, because the rise suppression effect on the back flow BF, which is gas flow rising along the inner wall of the vessel 110, uniformly acts throughout all the region in the circumferential direction, a weak point in the rise suppression of the back flow BF may be removed or reduced. Therefore, because the residue of the droplets DL is suppressed from accumulating in the vicinity of the second end 119 (see FIG. 1) of the vessel 110, issues of facility defects and mask defects due to particles generated by the spitting phenomenon may be reduced, and eventually, the reliability of a lithography process using a lithography apparatus may improve.

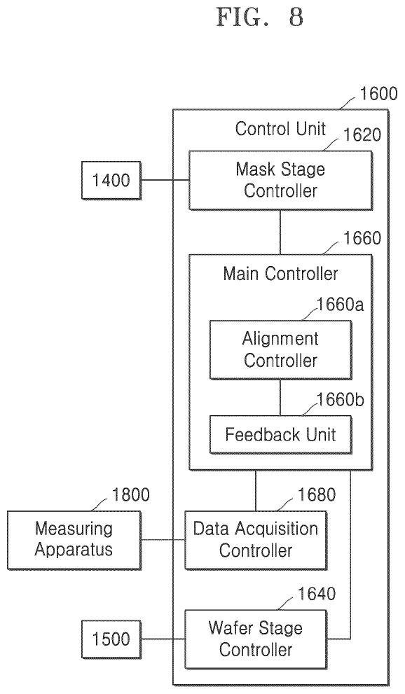

FIG. 7 is a diagram schematically illustrating a configuration of a lithography apparatus, according to some example embodiments. FIG. 8 is a diagram illustrating a control unit of FIG. 7 in detail, according to some example embodiments.

Referring to FIGS. 7 and 8, a lithography apparatus 1000 according to some example embodiments may include an EUV light source 1100, first optics 1200, second optics 1300, a mask stage 1400, a substrate stage 1500, a control unit 1600, and a measuring apparatus 1800.

In the lithography apparatus 1000 of FIGS. 7 and 8, the EUV light source 1100 may include, for example, a plasma-based light source. However, in the lithography apparatus 1000 of FIGS. 7 and 8, the EUV light source 1100 is not limited to the plasma-based light source. To increase the energy density of illumination light incident on the first optics 1200, the plasma-based light source may include a condensing mirror, such as an ellipsoidal mirror and/or a spherical mirror, which concentrates EUV light. The spitting phenomenon generated by the EUV light source 1100, which is included in the lithography apparatus 1000, may be reduced by the plurality of gas lock nozzles described in detail with reference to FIGS. 1 to 6, and thus, the amount of tin particles emitted out of the vessel 110 may be reduced, thereby improving the reliability of a process of EUV light irradiation onto an EUV mask M of the lithography apparatus 1000.

The first optics 1200 may include a plurality of mirrors. For example, in the lithography apparatus 1000 of FIGS. 7 and 8, the first optics 1200 may include two or three mirrors. However, the number of mirrors of the first optics 1200 is not limited to two or three. The first optics 1200 may transfer EUV light L1 from the EUV light source 1100 to the EUV mask M. For example, EUV light L1 from the EUV light source 1100 may be incident on the EUV mask M, which is arranged on the mask stage 1400, by reflection by the mirrors in the first optics 1200. The first optics 1200 may cause EUV light L1 to be formed in a curved slit shape and thus be incident on the EUV mask M. Here, the curved slit shape of EUV light L1 may refer to a 2-dimensional curve with a parabolic shape on the X-Y plane.

The EUV mask M may be a reflective mask including a reflection region and a non-reflection and/or medium-reflection region. The EUV mask M may include a reflective multilayer for EUV reflection, which is formed on a substrate including a low thermal expansion coefficient material (LTEM), such as quartz, and a pattern of an absorbing layer, which is formed on the reflective multilayer. The reflective multilayer may have, for example, a structure in which a molybdenum (Mo) layer and a silicon (Si) layer are alternately stacked in a total of tens of layers. The absorbing layer may include, for example, TaN, TaNO, TaBO, Ni, Au, Ag, C, Te, Pt, Pd, Cr, or the like. However, the respective materials of the reflective multilayer and the absorbing layer are not limited to the examples of materials set forth above. Here, the pattern of the absorbing layer may correspond to the non-reflection and/or medium-reflection region set forth above.

The EUV mask M reflects EUV light L1, which is incident through the first optics 1200, to be incident on the second optics 1300. For example, when the EUV mask M reflects EUV light L1 incident from the first optics 1200, the EUV mask M structuralizes EUV light L1, depending on the shapes of patterns of the reflective multilayer and the absorbing layer on the substrate, and causes the EUV light L1 to be incident on the second optics 1300. EUV light L1 may be structuralized to include at least second-order diffracted light, based on the patterns on the EUV mask M. The structuralized EUV light may be incident on the second optics 1300 while retaining information of the shapes of the patterns on the EUV mask M, and be projected on an EUV exposure object W through the second optics 1300 to form an image corresponding to the shapes of the patterns. Here, the EUV exposure object W may include a substrate, for example, a substrate including a semiconductor material, such as silicon. Hereinafter, the term “EUV exposure object W” is used interchangeably with the term “substrate” to have the same meaning, unless specifically stated otherwise.

The second optics 1300 may include a plurality of mirrors. Although FIG. 7 illustrates that the second optics 1300 includes two mirrors, that is, a first mirror 1320 and a second mirror 1340, this is only for convenience of illustration and the second optics 1300 may include more than two mirrors.

For example, in the lithography apparatus 1000 of FIGS. 7 and 8, the second optics 1300 may include four to eight mirrors. However, the number of mirrors of the second optics 1300 is not limited to four to eight.

The EUV mask M may be arranged on the mask stage 1400. The mask stage 1400 may move in the X direction and the Y direction on the X-Y plane and may move in the Z direction that is perpendicular to the X-Y plane. In addition, the mask stage 1400 may rotate about the Z axis on the X-Y plane or may rotate about one axis in the X-Y plane, for example, the X axis or the Y axis, on the Y-Z plane or the X-Z plane. By the movement of the mask stage 1400 as such, the EUV mask M may move in the X, Y, or Z direction and may rotate about the X, Y, or Z axis.

The EUV exposure object W, for example, a substrate, may be arranged on the substrate stage 1500. The substrate stage 1500 may move in the X direction and the Y direction on the X-Y plane and may move in the Z direction that is perpendicular to the X-Y plane. In addition, the substrate stage 1500 may rotate about the Z axis on the X-Y plane or may rotate about one axis in the X-Y plane, for example, the X axis or the Y axis, on the Y-Z plane or the X-Z plane. By the movement of the substrate stage 1500 as such, the EUV exposure object W may move in the X, Y, or Z direction and may rotate about the X, Y, or Z axis.

The control unit 1600 may control the mask stage 1400 and the substrate stage 1500. The control unit 1600 is described below in more detail with reference to FIG. 8.

The measuring apparatus 1800 may measure critical dimensions (CDs) or overlay errors for patterns on the substrate. The measuring apparatus 1800 may include an optical microscope or an electron microscope, such as a scanning electron microscope (SEM) or a transmission electron microscope (TEM). In addition, the measuring apparatus 1800 may use, as a measurement method, ellipsometry, such as imaging ellipsometry (IE) or spectroscopic imaging ellipsometry (SIE). However, the measurement method of the measuring apparatus 1800 is not limited to ellipsometry.

Although the lithography apparatus 1000 includes the measuring apparatus 1800 in some example embodiments, the measuring apparatus 1800 may be implemented to be a separate apparatus from the lithography apparatus 1000, depending on some example embodiments. The measurement of the CDs or overlay errors on the patterns on the substrate by the measuring apparatus 1800 may be performed as After Development Inspection (ADI) and After Cleaning Inspection (ACI).

To describe the control unit 1600 in more detail with reference to FIG. 8, the control unit 1600 may include a mask stage controller 1620, a wafer stage controller 1640, a main controller 1660, and a data acquisition controller 1680. By controlling the mask stage 1400 and the substrate stage 1500 via the control unit 1600, together with changing the tilted angles of the plurality of gas lock nozzles, as described with reference to FIGS. 1 to 6, the spitting phenomenon may be effectively reduced and the reliability of a process by the lithography apparatus 1000 may improve.

The mask stage controller 1620 may control the movement of the mask stage 1400. Here, the movement of the mask stage 1400 may include the movement in the X, Y, or Z direction and the rotation about the X, Y, or Z axis.

The wafer stage controller 1640 may control the movement of the substrate stage 1500. The movement of the substrate stage 1500 may also include the movement in the X, Y, or Z direction and the rotation about the X, Y, or Z axis.

The main controller 1660 may include an alignment controller 1660a and a feedback unit 1660b. The alignment controller 1660a may calculate correction values of parameters of an overlay error. The correction values of the parameters of the overlay error may be calculated based on data for the parameters of the overlay error and a correlation between the parameters of the overlay error. Here, the parameters of the overlay error may refer to parameters related to an overlay error between layers on the EUV exposure object W, for example, the substrate. Hereinafter, the parameters of the overlay error are simply referred to as “overlay parameters”.

For reference, an overlay error may refer to the difference in overlap between an underlayer and a current layer, which corresponds to an upper layer. In general, during an exposure process of the upper layer, a shot is performed on the upper layer after aligning the upper layer with the underlayer as accurately as possible based on overlay marks of the underlayer or the like. When the overlay error is great, in other words, when the difference in relative position between the underlayer and the current layer is great, the performance of a semiconductor device may be actually adversely affected.

In the lithography apparatus 1000 according to some example embodiments, for example, the alignment controller 1660a may calculate a correction value of a second overlay parameter from data for a first overlay parameter, based on a correlation between the first overlay parameter and the second overlay parameter. The feedback unit 1660b may feed back calculated correction values of overlay parameters to the mask stage controller 1620 and/or the wafer stage controller 1640. The mask stage controller 1620 and/or the wafer stage controller 1640 may control the movement of the mask stage 1400 and/or the substrate stage 1500 based on the correction values of the overlay parameters. For example, the feedback unit 1660b may feed back the calculated correction value of the second overlay parameter to the mask stage controller 1620, and the mask stage controller 1620 may control the rotation of the mask stage 1400 about the X-axis based on the correction value of the second overlay parameter.

The main controller 1660 may control the mask stage controller 1620 and the wafer stage controller 1640 on the whole. For example, during an exposure process, the main controller 1660 may control the mask stage controller 1620 and the wafer stage controller 1640 to synchronize the mask stage 1400 and the substrate stage 1500 with each other in a scan direction.

In addition, although not shown in FIG. 8, the main controller 1660 may further include various components for control in an EUV exposure process. For example, the main controller 1660 may include a focus controller, a data storage unit, an exposure processing unit, or the like.

The focus controller may calculate a focus correction value by comparing a measured focus offset with a required focus offset and may transfer the focus correction value to the wafer stage controller 1640 through the feedback unit 1660b such that the wafer stage controller 1640 may control the movement of the substrate stage 1500 in the Z direction or the like. The data storage unit may store data for the correction values of the overlay parameters, the correlation between the overlay parameters, the focus correction value, and the like, which are calculated by the alignment controller 1660a or the focus controller. After the movement of the mask stage 1400 and the substrate stage 1500 is controlled by the alignment controller 1660a, the focus controller, or the like, the exposure processing unit may perform an exposure process while the mask stage 1400 and the substrate stage 1500 are synchronized with each other in a scan direction by the main controller 1660.

When the measuring apparatus 1800 is included in the lithography apparatus 1000, the main controller 1660 may further include a measurement controller. The measurement controller may control the measuring apparatus 1800 to measure data related to the required overlay parameters.

The data acquisition controller 1680 may acquire data for the overlay parameters via the measuring apparatus 1800 and transfer the data to the main controller 1660. Specifically, the measuring apparatus 1800 may measure overlay errors for the patterns on the substrate, and the data acquisition controller 1680 may receive data for the overlay errors from the measuring apparatus 1800. As a result, the data acquisition controller 1680 may acquire the data for the required overlay parameters from the measuring apparatus 1800 and may transfer the data to the main controller 1660. In the lithography apparatus 1000 of some example embodiments, for example, the data acquisition controller 1680 may acquire data for a first overlay parameter via the measuring apparatus 1800 and may transfer the data to the alignment controller 1660a of the main controller 1660.

The lithography apparatus 1000 of some example embodiments may correct a second overlay parameter and thus correct the first overlay parameter, which has a correlation with the second overlay parameter, thereby significantly improving an overlay error in an EUV exposure process. The first overlay parameter may correspond to an overlay parameter that is unable to be corrected by physical actuation of the lithography apparatus 1000. The physical actuation may refer to a physical operation in a scanner, that is, an exposure apparatus, to correct an overlay error. For example, the physical actuation may include various methods, such as a method of applying pressure or a tilt to a lens or a mirror in optics or quickly moving the lens or the mirror, a method of moving a mask by the mask stage 1400 or moving the EUV exposure object W by the substrate stage 1500, and a method of heating the EUV exposure object W.

For reference, overlay parameters may be variously classified, and in particular, some of the overlay parameters are unable to be corrected due to hardware limitations of an EUV scanner or an EUV exposure apparatus.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

While the inventive concepts have been particularly shown and described with reference to example embodiments thereof, it will be understood that various changes in form and details may be made therein without departing from the spirit and scope of the following claims.

What is claimed is:

1. An extreme ultraviolet (EUV) light generating device comprising:
a vessel having an internal space;
a droplet generator configured to generate droplets that are to be supplied to the internal space of the vessel;
a droplet emitter configured to emit the droplets, generated by the droplet generator, to the internal space of the vessel;
a laser light source configured to generate a laser beam to generate EUV light by reaction with the droplets in the internal space of the vessel;
a condensing mirror arranged adjacent to the laser light source to surround at least a portion of the laser light source, the condensing mirror being configured to concentrate EUV light on an intermediate focus (IF); and
a plurality of gas lock nozzles arranged around the IF to respectively constitute a plurality of rows, each of the plurality of gas lock nozzles being configured to eject a flow control gas to the internal space of the vessel,
a gas lock nozzle in at least one of the plurality of rows being tilted in a direction that is consistent with a direction in which a sidewall of the vessel is tilted with respect to a central axis direction of the internal space of the vessel.

2. The EUV light generating device of claim 1, wherein a gas lock nozzle in at least one of the plurality of rows is tilted in a direction that is opposite to the direction in which the sidewall of the vessel is tilted with respect to the central axis direction of the internal space of the vessel.

3. The EUV light generating device of claim 1, wherein, based on a direction in which a gas lock nozzle constituting the plurality of rows being tilted with respect to the central axis direction of the internal space of the vessel is consistent with the direction in which the sidewall of the vessel is tilted with respect to the central axis direction of the internal space of the vessel, the flow of the flow control gas ejected from the gas lock nozzle is formed along a wall surface of the vessel, and,
based on a direction in which a gas lock nozzle constituting the plurality of rows being tilted with respect to the central axis direction of the internal space of the vessel is opposite to the direction in which the sidewall of the vessel is tilted with respect to the central axis direction of the internal space of the vessel, the flow of the flow control gas ejected from the gas lock nozzle is formed along the center of the internal space.

4. The EUV light generating device of claim 1, wherein
based on a direction in a gas lock nozzle constituting the plurality of rows being tilted with respect to the central axis direction of the internal space of the vessel is consistent with the direction in which the sidewall of the vessel is tilted with respect to the central axis direction of the internal space of the vessel, a difference between an angle, at which the gas lock nozzle in the at least one row is tilted with respect to the central axis direction of the internal space of the vessel, and an angle, at which the sidewall of the vessel is tilted with respect to the central axis direction of the internal space of the vessel, is 5 degrees (°) or less.

5. The EUV light generating device of claim 1, further comprising a plurality of gas locks respectively connected to the plurality of gas lock nozzles, the flow control gas to be ejected to the internal space of the vessel being introduced to each of the plurality of gas locks.

6. The EUV light generating device of claim 5, further comprising a plurality of gas sources respectively connected to the plurality of gas locks, each of the plurality of gas sources being configured to generate the flow control gas that is to be ejected to the internal space of the vessel.

7. The EUV light generating device of claim 1, further comprising:
an exhaust line on one side of the vessel; and
an exhaust unit configured to discharge a gas from the internal space of the vessel through the exhaust line.

8. The EUV light generating device of claim 1, further comprising:
a droplet flow path configured to guide the droplets generated by the droplet generator to the droplet emitter; and
a droplet collector configured to collect the droplets emitted from the droplet emitter.

9. The EUV light generating device of claim 1, wherein the flow control gas comprises hydrogen (H₂), helium (He), argon (Ar), hydrogen bromide (HBr), or a combination thereof.

10. The EUV light generating device of claim 1, further comprising a main gas source located vertically under the laser light source and configured to supply a gas forming an updraft in the internal space of the vessel.

11. An extreme ultraviolet (EUV) light generating device comprising:
a vessel having an internal space;
a droplet generator configured to generate droplets that are to be supplied to the internal space of the vessel;
a droplet emitter configured to emit the droplets, generated by the droplet generator, to the internal space of the vessel;
a laser light source configured to generate a laser beam to generate EUV light by reaction with the droplets in the internal space of the vessel;
a condensing mirror arranged adjacent to the laser light source to surround at least a portion of the laser light source, the condensing mirror being configured to concentrate EUV light on an intermediate focus (IF); and
a plurality of gas lock nozzles arranged around the IF to respectively constitute a plurality of rows, each of the plurality of gas lock nozzles being configured to eject a flow control gas to the internal space of the vessel,
a gas lock nozzle in at least one of the plurality of rows is tilted in a direction that is consistent with a direction in which a sidewall of the vessel is tilted with respect to a central axis direction of the internal space of the vessel, and
a difference between an angle, at which the gas lock nozzle in the at least one row is tilted with respect to the central axis direction of the internal space of the vessel, and an angle, at which the sidewall of the vessel is tilted with respect to the central axis direction of the internal space of the vessel, is 5 degrees (°) or less.

12. The EUV light generating device of claim 11, further comprising:
an exhaust line on one side of the vessel; and
an exhaust unit configured to discharge a gas from the internal space of the vessel through the exhaust line.

13. The EUV light generating device of claim 11, further comprising a plurality of gas locks respectively connected to the plurality of gas lock nozzles, the flow control gas to be ejected to the internal space of the vessel being introduced to each of the plurality of gas locks.

14. The EUV light generating device of claim 13, further comprising a plurality of gas sources respectively connected to the plurality of gas locks, each of the plurality of gas sources being configured to generate the flow control gas that is to be ejected to the internal space of the vessel.

15. The EUV light generating device of claim 11, wherein
based on a direction in which a gas lock nozzle constituting the plurality of rows being tilted with respect to the central axis direction of the internal space of the vessel is consistent with the direction in which the sidewall of the vessel is tilted with respect to the central axis direction of the internal space of the vessel, the flow of the flow control gas ejected from the gas lock nozzle is formed along a wall surface of the vessel, and,
based on a direction in which a gas lock nozzle constituting the plurality of rows being tilted with respect to the central axis direction of the internal space of the vessel is opposite to the direction in which the sidewall of the vessel is tilted with respect to the central axis direction of the internal space of the vessel, the flow of the flow control gas ejected from the gas lock nozzle is formed along the center of the internal space of the vessel.

16. The EUV light generating device of claim 11, wherein
the condensing mirror has an ellipsoidal geometrical structure having two focuses, and
the two focuses comprise a first focus corresponding to a position, at which the laser beam meets the droplets, and the IF.

17. The EUV light generating device of claim 11, further comprising:
a droplet flow path configured to guide the droplets generated by the droplet generator to the droplet emitter; and
a droplet collector configured to collect the droplets emitted from the droplet emitter.

18. The EUV light generating device of claim 11, further comprising a main gas source located vertically under the laser light source and configured to supply a gas forming an updraft in the internal space of the vessel.

19. An extreme ultraviolet (EUV) light generating device configured to output EUV light generating device that constitutes a lithography apparatus comprising;
first optics configured to cause EUV light, which is output from the EUV light generating device, to be incident on a mask that reflects EUV light;
second optics configured to cause EUV light, which is reflected by the mask, to be incident on a substrate;
a mask stage, on which the mask is arranged;
a substrate stage, on which the substrate is arranged,
a vessel having an internal space;
an exhaust line on one side of the vessel;
an exhaust unit configured to discharge a gas from the internal space of the vessel through the exhaust line;
a droplet generator configured to generate droplets that are to be supplied to the internal space of the vessel;
a droplet emitter configured to emit the droplets, generated by the droplet generator, to the internal space of the vessel;
a droplet flow path configured to guide the droplets generated by the droplet generator to the droplet emitter;
a droplet collector configured to collect the droplets emitted from the droplet emitter;
a laser light source configured to generate a laser beam to generate EUV light by reaction with the droplets in the internal space of the vessel;
a condensing mirror arranged adjacent to the laser light source to surround at least a portion of the laser light source, the condensing mirror being configured to concentrate EUV light on an intermediate focus (IF); and
a plurality of gas lock nozzles arranged around the IF to respectively constitute a plurality of rows, each of the plurality of gas lock nozzles being configured to eject a flow control gas to the internal space of the vessel,
a gas lock nozzle in at least one of the plurality of rows is tilted in a direction that is consistent with a direction in which a sidewall of the vessel is tilted with respect to a central axis direction of the internal space of the vessel, and
a difference between an angle, at which the gas lock nozzle in the at least one row is tilted with respect to the central axis direction of the internal space of the vessel, and an angle, at which the sidewall of the vessel is tilted with respect to the central axis direction of the internal space of the vessel, is 5 degrees (°) or less.

20. The EUV light generating device of claim 19, further comprising a control unit configured to control the mask stage and the substrate stage.
